(19) United States
(12) Patent Application Publication
(10) Pub. No.: US 2026/0255473 A1
(43) Pub. Date: Aug. 27, 2026

(54) PRINTED CIRCUIT BOARD

(71) Applicant: SAMSUNG ELECTRO-MECHANICS CO., LTD., Suwon-si (KR)

(72) Inventors: Tae Hong Min, Suwon-si (KR); Hyuck Choo, Suwon-si (KR); Ki Suk Kim, Suwon-si (KR)

(73) Assignee: SAMSUNG ELECTRO-MECHANICS CO., LTD., Suwon-si (KR)

(21) Appl. No.: 19/453,915

(22) Filed: Jan. 20, 2026

(30) Foreign Application Priority Data
Feb. 24, 2025 (KR) 10-2025-0023915
May 30, 2025 (KR) 10-2025-0070952

(51) Int. Cl. H05K 1/02; H05K 1/03; H05K 1/11

(52) U.S. Cl. CPC H05K 1/0271; H05K 1/0306; H05K 1/0313; H05K 1/115; H05K 2201/09481; H05K 2201/09527; H05K 2201/09618; H05K 2201/09827

(57) ABSTRACT

A printed circuit board includes a plurality of first insulating layers, a plurality of first wiring layers respectively disposed in the plurality of first insulating layers, a first glass layer disposed on an upper side of the plurality of first insulating layers, the first glass layer having a thickness less than that of one of the plurality of first insulating layers, a second glass layer disposed on a lower side of the plurality of first insulating layers, the second glass layer having a thickness less than that of the one of the plurality of first insulating layers, a second wiring layer disposed on an upper side of the first glass layer, and a third wiring layer disposed on a lower side of the second glass layer.

### CROSS-REFERENCE TO RELATED APPLICATIONS

This application claims benefit of priority to Korean Patent Application Nos. 10-2025-0023915 filed on Feb. 24, 2025 and 10-2025-0070952 filed on May 30, 2025 in the Korean Intellectual Property Office, the disclosures of which are incorporated herein by reference in their entirety.

### TECHNICAL FIELD

The present disclosure relates to a printed circuit board.

With the recent surge in demand for high-performance computing and large-scale data processing, the semiconductor application market centered on servers has been rapidly expanding. In response, demand for large-area substrates for high integration and high bandwidth processing has been increasing, and miniaturization and high-performance implementation of substrates and packages has been continuously progressing. For example, as demand increases for chiplets and heterogeneous integration packages in which distributed functions are implemented by integrating a plurality of chips within a single package, the importance of techniques of reducing spacings between fine wirings, securing overall planarity of packages and substrates, and suppressing warpage has been emerging. However, substrate technologies using organic material-based copper-clad laminates according to the related art have shown limitations in terms of pitch reduction and warpage control. In particular, for server central processing units, technological development has been increasing toward reducing the overall thickness by shifting from a structure with a core layer to a structure without a core layer in which upper circuits are concentrated, while at the same time implementing high performance, and therefore, greater challenges have arisen in terms of warpage control.

### SUMMARY

An aspect of the present disclosure is to provide a printed circuit board that is applicable to a high-multilayer, large-area product, that enables implementation of thickness reduction, size reduction, and high performance, and that is more advantageous in terms of pitch reduction and warpage control.

A multilayer coreless substrate may be manufactured, a glass layer may be disposed on upper and lower sides of the multilayer coreless substrate, and then a wiring layer may be formed on each of the glass layers or an additional thin insulating layer on an upper glass layer.

According to an aspect of the present disclosure, there is provided a printed circuit board including a plurality of first insulating layers, a plurality of first wiring layers respectively disposed in the plurality of first insulating layers, a first glass layer disposed on an upper side of the plurality of first insulating layers, the first glass layer having a thickness less than that of one of the plurality of first insulating layers, a second glass layer disposed on a lower side of the plurality of first insulating layers, the second glass layer having a thickness less than that of the one of the plurality of first insulating layers, a second wiring layer disposed on an upper side of the first glass layer, and a third wiring layer disposed on a lower side of the second glass layer.

According to another aspect of the present disclosure, there is provided a printed circuit board including a first substrate portion including a first insulating body, a first glass layer disposed on an upper surface of the first insulating body, a second glass layer disposed on a lower surface of the first insulating body, and a plurality of internal wiring layers respectively disposed in the first insulating body, and a second substrate portion including a second insulating body disposed on an upper surface of the first glass layer, and a plurality of first external wiring layers respectively disposed on or in the second insulating body. An insulation distance between two first external wiring layers adjacent to each other in a thickness direction, among the plurality of first external wiring layers, may be less than an insulation distance between two internal wiring layers adjacent to each other in the thickness direction, among the plurality of internal wiring layers.

According to another aspect of the present disclosure, there is provided a printed circuit board including a plurality of first insulating layers, a plurality of first wiring layers respectively disposed in the plurality of first insulating layers, a plurality of first wiring vias respectively penetrating one or more of the plurality of first insulating layers, the plurality of first wiring vias connecting the plurality of first wiring layers to each other, a first glass layer disposed on an upper side of the plurality of first insulating layers, a second wiring layer disposed on an upper side of the first glass layer, a second wiring via penetrating at least through the first glass layer, the second wiring via connecting an uppermost first wiring layer, among the plurality of first wiring layers, and the second wiring layer to each other, and a second glass layer disposed on a lower side of the plurality of first insulating layers, a third wiring layer disposed on a lower side of the second glass layer, and a third wiring via penetrating the second glass layer, the third wiring via connecting a lowermost first wiring layer, among the plurality of first wiring layers, and the third wiring layer to each other. The plurality of first wiring vias may be respectively tapered in substantially the same direction as the second wiring via, and may be respectively tapered in substantially an opposite direction to the third wiring via. The third wiring via may be tapered from the third wiring layer to the lowermost first wiring layer.

According to example embodiments of the present disclosure, a printed circuit board may be applicable to a high-multilayer, large-area product, may enable implementation of thickness reduction, size reduction, and high performance, and may be more advantageous in terms of pitch reduction and warpage control.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram of an example of an electronic device system;

FIG. 2 is a schematic cross-sectional view of an example of a printed circuit board;

FIG. 3 is a schematic process diagram of an example of a method of manufacturing the printed circuit board of FIG. 2;

FIG. 4 is a schematic cross-sectional view of another example of a printed circuit board;

FIG. 5 is a schematic process diagram of an example of a method of manufacturing the printed circuit board of FIG. 4;

FIG. 6 is a schematic cross-sectional view of another example of a printed circuit board; and

FIG. 7 is a schematic cross-sectional view of another example of a printed circuit board.

### DETAILED DESCRIPTION

Hereinafter, the present disclosure will be described with reference to the accompanying drawings. In the drawings, the shapes, sizes, and the like of components may be exaggerated or reduced for clarity of description.

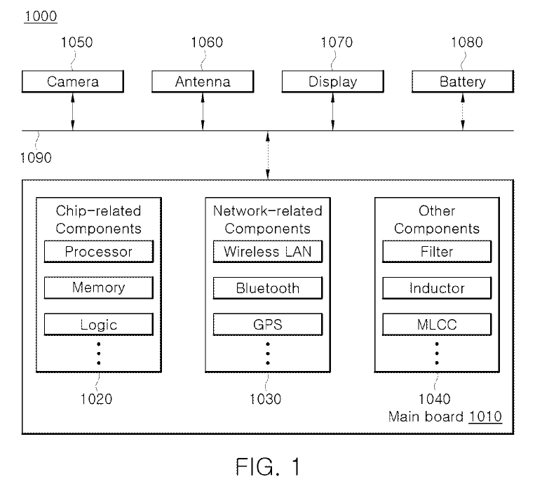

FIG. 1 is a schematic block diagram of an example of an electronic device system.

Referring to the drawings, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high-frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

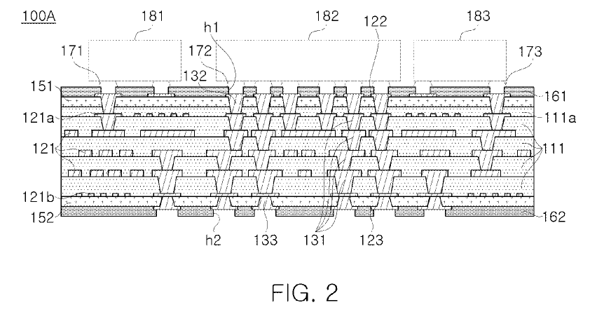

FIG. 2 is a schematic perspective view of an example of an electronic device.

Referring to the drawings, a printed circuit board 100A according to an example may include a plurality of first insulating layers 111 and 111a, a plurality of first wiring layers 121, 121a, and 121b respectively disposed in the plurality of first insulating layers 111 and 111a, a first glass layer 151 disposed on an upper side of the plurality of first insulating layers 111 and 111a, a second glass layer 152 disposed on a lower side of the plurality of first insulating layers 111 and 111a, a second wiring layer 122 disposed on an upper side of the first glass layer 151, a third wiring layer 123 disposed on a lower side of the second glass layer 152, a plurality of first wiring vias 131 respectively penetrating one or more of the plurality of first insulating layers 111 and 111a, the plurality of first wiring vias 131 connecting the plurality of first wiring layers 121, 121a, and 121b to each other, a second wiring via 132 penetrating both an uppermost first insulating layer 111a and the first glass layer 151, the second wiring via 132 connecting an uppermost first wiring layer 121a and the second wiring layer 122 to each other, a third wiring via 133 penetrating the second glass layer 152, the third wiring via 133 connecting a lowermost first wiring layer 121b and the third wiring layer 123 to each other, a first solder resist layer 161 disposed on the upper side of the first glass layer 151, the first solder resist layer 161 having a plurality of first openings h1 respectively exposing at least a portion of the second wiring layer 122, and a second solder resist layer 162 disposed on the lower side of the second glass layer 152, the second solder resist layer 162 having a plurality of second openings h2 respectively exposing at least a portion of the third wiring layer 123. A plurality of semiconductor chips 181, 182, and 183 may be mounted on the first solder resist layer 161 through a plurality of electrical connection metals 171, 172, and 173, as necessary. For example, the printed circuit board 100A according to an example may be a package substrate, an interposer substrate, and/or a semiconductor package.

The plurality of first insulating layers 111 and 111a, the plurality of first wiring layers 121, 121a, and 121b, and the plurality of first wiring vias 131 may be a coreless-type multilayer substrate structure. For example, the plurality of first insulating layers 111 and 111a may not include an additional core layer. For example, the plurality of first insulating layers 111 and 111a may be a coreless structure including a plurality of build-up layers. In addition, the first and second glass layers 151 and 152 may be respectively disposed on an upper side and a lower side of the coreless multilayer substrate structure. In this case, the first and second glass layers 151 and 152 may respectively have a thickness less than that of at least one of the plurality of first insulating layers 111 and 111a, preferably at least one of remaining first insulating layers 111 excluding the uppermost first insulating layer 111a. Accordingly, the printed circuit board 100A according to an example may be applicable to a high-multilayer, large-area product including 50 or more build-up layers or 100 or more build-up layers, may enable thinning despite such application, and may at the same time be more advantageous in terms of warpage control. In addition, by applying the first glass layer 151 having excellent planarity, the second wiring layer 122 including a fine wiring may be formed on an outermost side of the printed circuit board 100A on which the plurality of semiconductor chips 181, 182, and 183 are mounted, and thus size reduction and high performance may be more advantageously implemented, and it also may be more advantageous in terms of pitch reduction.

Hereinafter, components of the printed circuit board 100A will be described in more detail with reference to the drawings.

The plurality of first insulating layers 111 and 111a may respectively include an organic insulating material. The organic insulating material may include a thermosetting resin such as an epoxy resin, a thermoplastic resin such as polyimide, or a material including an inorganic filler and/or an organic filler together with a resin. For example, the plurality of first insulating layers 111 and 111a may respectively include a non-photosensitive insulating material such as an Ajinomoto Build-up Film (ABF), or a photosensitive insulating material such as a photoimageable dielectric (PID), but the present disclosure is not limited thereto. The plurality of first insulating layers 111 and 111a may be distinguished from each other, but may also be integrated with each other without a boundary therebetween. When integrated with each other, an interlayer boundary between the plurality of first insulating layers 111 and 111a may be approximately predicted based on a lower surface of each of a plurality of wiring layers 121, 121a, and 121b.

The plurality of first wiring layers 121, 121a, and 121b, and the second and third wiring layers 122 and 123 may respectively include a metal. The metal may include copper (Cu), aluminum (Al), silver (Ag), tin (Sn), gold (Au), nickel (Ni), lead (Pb), titanium (Ti), and/or alloys thereof. The plurality of first wiring layers 121, 121a, and 121b, and the second and third wiring layers 122 and 123 may respectively perform various functions depending on a design thereof. For example, the plurality of first wiring layers 121, 121a, and 121b, and the second and third wiring layers 122 and 123 may include a signal pattern, a power pattern, a ground pattern, or the like. The above-described patterns may respectively have various forms such as a line, a plane, a pad, a land, and the like. The plurality of first wiring layers 121, 121a, and 121b, and the second and third wiring layers 122 and 123 may respectively include an electroless plating layer (for example, chemical copper) as a seed layer and an electrolytic plating layer (for example, electrolytic copper) as a pattern layer, but the present disclosure is not limited thereto. The plurality of first wiring layers 121, 121a, and 121b, and the second and third wiring layers 122 and 123 may include a sputtered layer (for example, sputtered titanium/copper) instead of the electroless plating layer as a seed layer. Alternatively, the plurality of first wiring layers 121, 121a, and 121b, and the second and third wiring layers 122 and 123 may include both a sputtered layer and an electroless plating layer as a seed layer.

The uppermost first wiring layer 121a, the second wiring layer 122, the lowermost first wiring layer 121b, and the third wiring layer 123 may respectively have a thickness less than that of at least one of remaining first wiring layers 121. For example, the wiring layers 121a, 121b, 122, and 123, formed on the outermost side of the printed circuit board 100A according to an example, may be formed as thinner and finer wiring layers. In particular, the wiring layers 121a and 122, disposed on the outermost side of the printed circuit board 100A on which a semiconductor chip is mounted, may be formed as thinner wiring layers, such that size reduction and high performance may be more advantageously implemented, and it also may be more advantageous in terms of pitch reduction. Only the uppermost first wiring layer 121a and the second wiring layer 122 may respectively have a thickness less than that of at least one of the remaining first wiring layers 121, as necessary, but the present disclosure is not limited thereto.

The plurality of first wiring vias 131 and the second and third wiring vias 132 and 133 may respectively include a metal. The metal may include copper (Cu), aluminum (Al), silver (Ag), tin (Sn), gold (Au), nickel (Ni), lead (Pb), titanium (Ti), and/or alloys thereof. The plurality of first wiring vias 131 and the second and third wiring vias 132 and 133 may respectively include a filled via filling a via hole, but may also include a conformal via disposed along a wall surface of the via hole. The plurality of first wiring vias 131 and the second and third wiring vias 132 and 133 may respectively perform various functions depending on a design thereof. For example, the plurality of first wiring vias 131 and the second and third wiring vias 132 and 133 may include a ground via, a power via, a signal via, or the like. The plurality of first wiring vias 131 and the second and third wiring vias 132 and 133 may respectively include an electroless plating layer (for example, chemical copper) as a seed layer and an electrolytic plating layer (for example, electrolytic copper) as a pattern layer, but the present disclosure is not limited thereto. The plurality of first wiring vias 131 and the second and third wiring vias 132 and 133 may include a sputtered layer (for example, sputtered titanium/copper) instead of the electroless plating layer as a seed layer. Alternatively, the plurality of first wiring vias 131 and the second and third wiring vias 132 and 133 may include both a sputtered layer and an electroless plating layer as a seed layer.

The plurality of first wiring vias 131 may be respectively tapered in substantially the same direction as the second wiring via 132, and may be respectively tapered in substantially an opposite direction to the third wiring via 133. For example, a width of an upper end of each of the plurality of first wiring vias 131 and the second wiring via 132 may be greater than a width of a lower end of each of the plurality of first wiring vias 131 and the second wiring via 132 in cross-section. Conversely, a width of an upper end of the third wiring via 133 may be less than a width of a lower end of the third wiring via 133 in cross-section. In addition, the second wiring via 132 may penetrate both the first glass layer 151 and the uppermost first insulating layer 111a. The first to third wiring vias 131, 132, and 133 having such a structure may be implemented by forming a multilayer coreless substrate using a carrier, attaching a glass layer after detaching the carrier, and processing a via in an outermost layer, as in a process to be described below. As a result, it may be more advantageous to implement the above-described technical effects.

The first and second glass layers 151 and 152 may respectively include glass that is an amorphous solid. Glass may include, for example, pure silicon dioxide (about 100% SiO₂), soda lime glass, borosilicate glass, aluminosilicate glass, or the like, but the present disclosure is not limited thereto. An alternative glass material, such as fluorine glass, phosphate glass, chalcogen glass, or the like, may also be used as a material. In addition, other additives may be further included to form glass having specific physical properties. Such additives may include calcium carbonate (for example, lime) and sodium carbonate (for example, soda), as well as magnesium, calcium, manganese, aluminum, lead, boron, iron, chromium, potassium, sulfur, and antimony, and carbonates and/or oxides of the above-described elements and other elements. The first and second glass layers 151 and 152 may be layers distinguished from an organic insulating material including a glass fiber (glass cloth or glass fabric), for example, a copper clad laminate (CCL), a prepreg (PPG), or the like. For example, the first and second glass layers 151 and 152 may include a glass panel that may be implemented as a large-area glass substrate, such as a glass plate.

The first and second solder resist layers 161 and 162 may respectively include a liquid or film-type solder resist, but the present disclosure is not limited thereto, and other types of insulating materials such as an ABF or the like may also be used. A surface treatment layer and/or a metal bump may be formed on each of patterns exposed through a plurality of first and second openings h1 and h2, as necessary. Each of the patterns exposed through the plurality of first and second openings h1 and h2 may be in the form of a solder mask defined (SMD) and/or a non-solder mask defined (NSMD), but the present disclosure is not limited thereto.

The plurality of electrical connection metals 171, 172, and 173 may be respectively formed of a low melting point metal, for example, a solder such as tin (Sn)-aluminum (Al)-Copper (Cu), or the like, but the material is only an example, and is not limited thereto. The plurality of electrical connection metals 171, 172, and 173 may be respectively in the form of a ball, a pin, or the like. The plurality of electrical connection metals 171, 172, and 173 may be respectively formed as multiple layers or a single layer. The plurality of electrical connection metals 171, 172, and 173 may include a copper pillar and a solder when formed of multiple layers, and may include a tin-silver solder when formed of a single layer, but the present disclosure is not limited thereto. The plurality of electrical connection metals 171, 172, and 173 may be respectively used for mounting the plurality of semiconductor chips 181, 182, and 183.

The plurality of semiconductor chips 181, 182, and 183 may respectively include an integrated circuit (IC) die in which hundreds to millions of devices are integrated within a single chip. The integrated circuit may be, for example, a logic chip such as a central processing unit (for example, CPU), a graphics processing unit (for example, GPU), a field-programmable gate array (for example, FPGA), a digital signal processor, a cryptographic processor, a microprocessor, a microcontroller, or an application processor (for example, AP), an analog-digital converter, or an application-specific IC (ASIC), but the present disclosure is not limited thereto. The integrated circuit may be another type, such as a memory chip including volatile memory (for example, DRAM), non-volatile memory (for example, ROM), flash memory, or high bandwidth memory (HBM). In addition, the integrated circuit may be a semiconductor chip in which circuits controlling various input/output devices, such as an input/output die (for example, I/O die), are collected. For example, the first and third semiconductor chips 181 and 183 may respectively be central processing units (for example, CPUs), and the second semiconductor chip 182 may be an input/output die (for example, an I/O die), but the present disclosure is not limited thereto.

A passive device such as a silicon capacitor (Si-Cap) or an integrated passive device (IPD) may be embedded in the plurality of first insulating layers 111 and 111a, as necessary. The embedded passive device may be connected to at least one of the plurality of first wiring vias 131 and may thereby be connected to at least one of the plurality of first wiring layers 121, 121a, and 121b. Accordingly, the embedded passive device may be electrically connected to at least one of the plurality of semiconductor chips 181, 182, and 183.

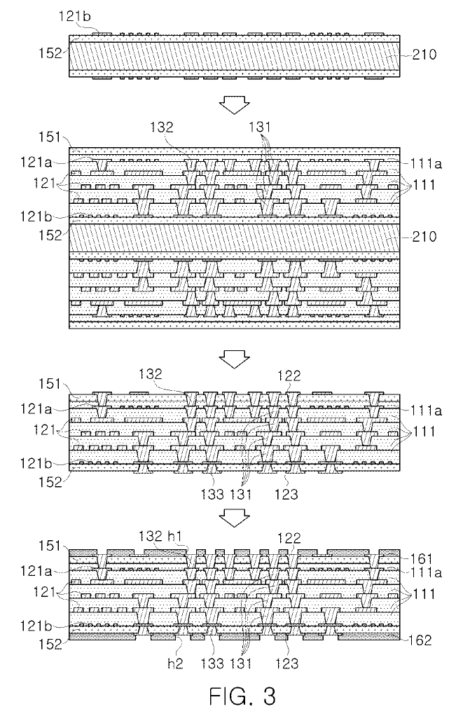

FIG. 3 is a schematic process diagram of an example of a method of manufacturing the printed circuit board of FIG. 2.

First, a carrier 210 may be prepared. The carrier 210 may be, for example, a glass carrier, but the present disclosure is not limited thereto. A second glass layer 152 may be attached to the carrier 210. A first wiring layer 121b may be formed on the second glass layer 152. The first wiring layer 121b may be formed using a high-resolution dry patterning (HRDP) technique. A process may be performed symmetrically on an upper side and a lower side of the carrier 210.

Subsequently, a plurality of first insulating layers 111 and 111a, a remaining plurality of first wiring layers 121, 121a, and 121b, and a plurality of first wiring vias 131 may be formed on the second glass layer 152. For example, a multilayer coreless substrate structure may be formed through a build-up process. A first glass layer 151 may be attached to an uppermost first insulating layer 111a. A process may be performed symmetrically on the upper side and the lower side of the carrier 210.

Subsequently, detachment from the carrier 210 may be performed. After detachment, second and third wiring layers 122 and 123 and second and third wiring vias 132 and 133 may be formed. For example, a first via hole, penetrating the first glass layer 151 and the uppermost first insulating layer 111a, and a second via hole, penetrating the second glass layer 152, may be formed, a seed layer may be formed by performing sputtering or electroless plating, and the second and third wiring layers 122 and 123 and the second and third wiring vias 132 and 133 may be formed by performing electrolytic plating.

Subsequently, first and second solder resist layers 161 and 162 may be formed on the first and second glass layers 151 and 152, respectively. The first and second solder resist layers 161 and 162 may be formed by coating a liquid-type material and then curing the liquid-type material or by laminating a film-type material and then curing the film-type material. In addition, a plurality of first and second openings h1 and h2 may respectively be formed in the first and second solder resist layers 161 and 162. The plurality of first and second openings h1 and h2 may be formed through a photolithography process. Thereafter, a plurality of semiconductor chips may be mounted using a plurality of electrical connection metals, as necessary.

Through a series of processes, the printed circuit board 100A according to an example may be manufactured. Other descriptions may be substantially the same as the above descriptions.

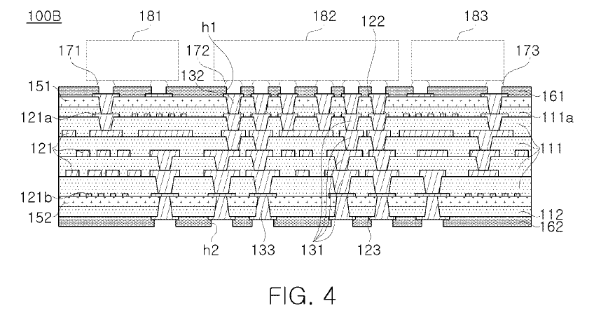

FIG. 4 is a schematic cross-sectional view of another example of a printed circuit board.

Referring to the drawings, as compared to the printed circuit board 100A according to an example, a printed circuit board 100B according to another example may further include a second insulating layer 112 disposed between a second glass layer 152 and a third wiring layer 123. In this case, a third wiring via 133 may further penetrate the second insulating layer 112. For example, the third wiring via 133 may penetrate both the second glass layer 152 and the second insulating layer 112. Introduction of the second insulating layer 112 may improve adhesion of the third wiring layer 123 and may improve process reliability.

The second insulating layer 112 may include an organic insulating material. The organic insulating material may include a thermosetting resin such as epoxy resin, a thermoplastic resin such as polyimide, or a material including an inorganic filler and/or an organic filler together with a resin. For example, the second insulating layer 112 may include a non-photosensitive insulating material such as an ABF or a photosensitive insulating material such as a PID, but the present disclosure is not limited thereto.

Other descriptions may be substantially the same as the above descriptions of the printed circuit board 100A according to an example.

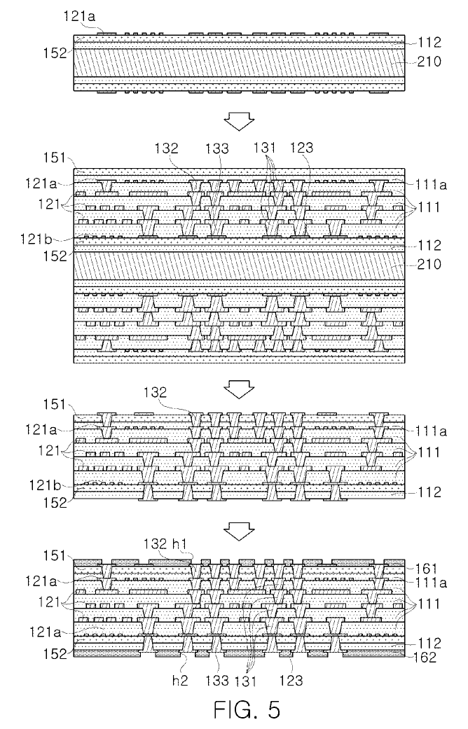

FIG. 5 is a schematic process diagram of an example of a method of manufacturing the printed circuit board of FIG. 4.

First, a carrier 210 may be prepared. The carrier 210 may be, for example, a carrier formed of a glass material or a carrier formed of a copper clad laminate material, but the present disclosure is not limited thereto. A second glass layer 152 may be attached to the carrier 210 through a second insulating layer 112. Accordingly, the second glass layer 152 may be more stably attached, and process reliability in subsequent processes may be further improved. A first wiring layer 121b may be formed on the second glass layer 152. The first wiring layer 121b may be formed using an HRDP technique. A process may be performed symmetrically on an upper side and a lower side of the carrier 210.

Subsequently, a plurality of first insulating layers 111 and 111a, a remaining plurality of first wiring layers 121, 121a, and 121b, and a plurality of first wiring vias 131 may be formed on the second glass layer 152. For example, a multilayer coreless substrate structure may be formed through a build-up process. A first glass layer 151 may be attached to an uppermost first insulating layer 111a. A process may be performed symmetrically on the upper side and the lower side of the carrier 210.

Subsequently, detachment from the carrier 210 may be performed. After detachment, second and third wiring layers 122 and 123 and second and third wiring vias 132 and 133 may be formed. For example, a first via hole, penetrating the first glass layer 151 and the uppermost first insulating layer 111a, and a second via hole, penetrating the second glass layer 152 and the second insulating layer 112, may be formed. A seed layer may be formed by performing sputtering or electroless plating, and the second and third wiring layers 122 and 123 and the second and third wiring vias 132 and 133 may be formed by performing electrolytic plating.

Subsequently, first and second solder resist layers 161 and 162 may be respectively formed on the first glass layer 151 and the second insulating layer 112. The first and second solder resist layers 161 and 162 may be formed by coating a liquid-type material and then curing the liquid-type material or by laminating a film-type material and then curing the film-type material. In addition, a plurality of first and second openings h1 and h2 may be respectively formed in the first and second solder resist layers 161 and 162. The plurality of first and second openings h1 and h2 may be respectively formed through a photolithography process. Subsequently, a plurality of semiconductor chips may be mounted using a plurality of electrical connection metals, as necessary.

Through a series of processes, the printed circuit board 100B according to another example may be manufactured. Other descriptions may be substantially the same as the above descriptions.

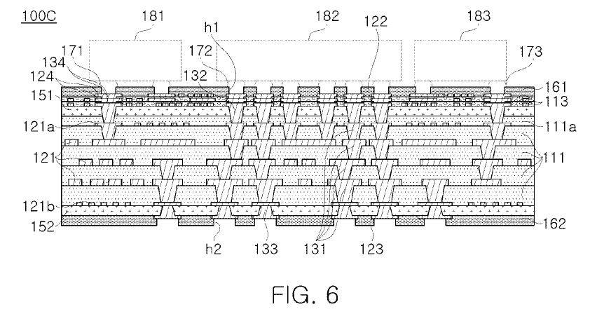

FIG. 6 is a schematic cross-sectional view of another example of a printed circuit board.

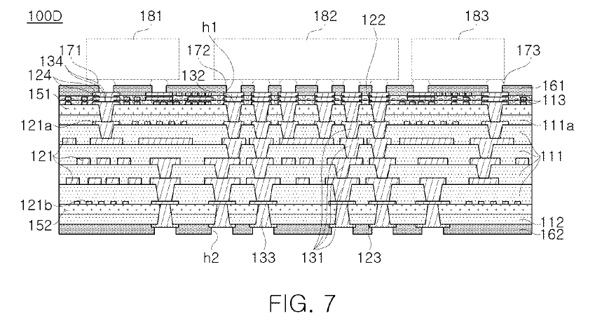

FIG. 7 is a schematic cross-sectional view of another example of a printed circuit board.

Referring to the drawings, as compared to the printed circuit boards 100A and 100B, printed circuit boards 100C and 100D according to another example may respectively further include a plurality of third insulating layers 113 disposed on an upper side of a first glass layer 151, a plurality of fourth wiring layers 124 respectively disposed on the plurality of third insulating layers 113, and a plurality of fourth wiring vias 134 respectively penetrating at least one of the plurality of third insulating layers 113, connecting the plurality of fourth wiring layers 124 to each other, and connecting a lowermost fourth wiring layer 124 and a second wiring layer 122 to each other. For example, in the printed circuit boards 100C and 100D according to another example, a fine wiring layer may be further formed on the upper side of the first glass layer 151. In this case, a first solder resist layer 161 may be disposed on an upper side of the plurality of third insulating layers 113, and a plurality of first openings h1 may respectively expose at least a portion of an uppermost fourth wiring layer 124.

The plurality of third insulating layers 113 may respectively include an inorganic insulating material. The inorganic insulating material may be, for example, silicon oxide or silicon nitride, but the present disclosure is not limited thereto. In a semiconductor process, other inorganic insulating materials, used as materials of an inorganic insulating film, may also be used. For example, the plurality of third insulating layers 113 may respectively include silicon dioxide (SiO₂), silicon nitride (SiN), aluminum oxide (Al₂O₃), hafnium oxide (HfO₂), zirconium oxide (ZrO₂), titanium oxide (TiO₂), boron nitride (BN), and/or silicon carbide (SiC), but the present disclosure is not limited thereto. The plurality of third insulating layers 113 may be distinguished from each other, or may be integrated with each other without a boundary therebetween. When integrated with each other, an interlayer boundary between the plurality of third insulating layers 113 may be approximately predicted based on a lower surface of each of a plurality of wiring layers 124. The plurality of third insulating layers 113 may respectively have a thickness less than that of each of the plurality of first insulating layers 111 and 111a and the first and second glass layers 151 and 152. Accordingly, it may be more advantageous for formation of a fine wiring layer.

The plurality of fourth wiring layers 124 may respectively include a metal. The metal may include copper (Cu), aluminum (Al), silver (Ag), tin (Sn), gold (Au), nickel (Ni), lead (Pb), titanium (Ti), and/or alloys thereof. The plurality of fourth wiring layers 124 may respectively perform various functions depending on a design thereof. For example, the plurality of fourth wiring layers 124 may include a signal pattern, a power pattern, a ground pattern, or the like. The above-described patterns may respectively have various forms such as a line, a plane, a pad, a land, and the like. The plurality of fourth wiring layers 124 may respectively include a sputtered layer (for example, sputter titanium/copper) as a seed layer and an electrolytic plating layer (for example, electrolytic copper) as a pattern layer, but the present disclosure is not limited thereto. The plurality of fourth wiring layers 124 may respectively include an electroless plating layer (for example, chemical copper) as a seed layer. Alternatively, the seed layer may include both a sputtered layer and an electroless plating layer. The plurality of fourth wiring layers 124 may respectively have a thickness less than that of at least one of a plurality of first wiring layers 121, 121a, and 121b, preferably each of remaining first wiring layers 121 excluding uppermost and lowermost first wiring layers. Accordingly, it may be more advantageous for formation of a fine wiring layer. For example, the plurality of fourth wiring layers 124 may respectively have a thickness of 1 μm or less, and may respectively have a line/space of 3 μm/3 μm or less, but the present disclosure is not limited thereto.

The plurality of fourth wiring vias 134 may respectively include a metal. The metal may include copper (Cu), aluminum (Al), silver (Ag), tin (Sn), gold (Au), nickel (Ni), lead (Pb), titanium (Ti), and/or alloys thereof. The plurality of fourth wiring vias 134 may respectively include a filled via filling a via hole, but may also include a conformal via disposed along a wall surface of the via hole. The plurality of fourth wiring vias 134 may respectively perform various functions depending on a design thereof. For example, the plurality of fourth wiring vias 134 may include a ground via, a power via, a signal via, or the like. The plurality of fourth wiring vias 134 may respectively include a sputtered layer (for example, sputter titanium/copper) as a seed layer and an electrolytic plating layer (for example, electrolytic copper) as a pattern layer, but the present disclosure is not limited thereto. The plurality of fourth wiring vias 134 may respectively include an electroless plating layer (for example, chemical copper) as a seed layer. Alternatively, the plurality of fourth wiring vias 134 may respectively include both a sputtered layer and an electroless plating layer as a seed layer. The plurality of fourth wiring vias 134 may respectively have a diameter less than that of each of a plurality of first wiring vias 131. Accordingly, it may be more advantageous for formation of a fine wiring layer. The plurality of fourth wiring vias 134 may be respectively tapered in substantially the same direction as the plurality of first wiring vias 131 and a second wiring via 132, and may be respectively tapered in a direction substantially opposite to a third wiring via 133.

The plurality of first insulating layers 111 and 111a may be a first insulating body, the plurality of first wiring layers 121, 121a, and 121b may be a plurality of internal wiring layers, and the plurality of first wiring vias 131 and the second and third wiring vias 132 and 133 may be a plurality of internal wiring vias. The first insulating body, the plurality of internal wiring layers, the plurality of internal wiring vias, and the first and second glass layers 151 and 152 may be included in a first substrate portion. In addition, the plurality of third insulating layers 113 may be a second insulating body, the plurality of fourth wiring layers 124 may be a plurality of first external wiring layers, and the plurality of fourth wiring vias 134 may be a plurality of first external wiring vias. The second insulating body, the plurality of first external wiring layers, and the plurality of first external wiring vias may be included in a second substrate portion. In addition, the third wiring layer 123 may be a third external wiring layer. From such a perspective, the first insulating body of the first substrate portion may be a coreless structure including a plurality of build-up layers. In addition, at least one of the plurality of first external wiring layers of the second substrate portion may include a relatively high-density wiring compared to at least one of the plurality of internal wiring layers of the first substrate portion. In addition, the first insulating body of the first substrate portion may include one or more of a non-photosensitive organic insulating material and a photosensitive organic insulating material, and the second insulating body of the second substrate portion may include one or more of a silicon oxide film and a silicon nitride film.

Other descriptions may be substantially the same as the above descriptions of the printed circuit boards 100A and 100B according to an example and another example.

As used herein, line width, spacing, thickness, width, length, pitch, depth, or the like may be measured using a scanning microscope or an optical microscope, based on a cross-section of a printed circuit board obtained by polishing or cutting. The cut cross-section may be a vertical cross-section or a horizontal cross-section, and each value may be measured based on a required cut cross-section. When values are not consistent, a value may be determined as an average value of values measured at arbitrary five points. A width of an upper end and/or a lower end of a via may be measured on a cross-section obtained by cutting a substrate in a thickness direction along a central axis of the via. A depth of the via may be measured as a distance from the upper end to the lower end of the via on a cross-section obtained by cutting the substrate in the thickness direction along the central axis of the via.

As used herein, the terms “cover,” “to cover,” and “covering” may include entirely covering as well as at least partially covering, and may include directly covering as well as indirectly covering. In addition, the terms “fill,” to fill,” and “filling” may include not only completely filling, but also approximately filling, for example, may include a case in which some voids, pores or the like are present.

As used herein, “substantially” may be determined to include process variations or positional deviations occurring during manufacturing, as well as measurement errors. For example, “substantially equal” in terms of line width, spacing, thickness, or height may include not only values that are exactly equal, but also values that are approximately similar. In addition, “substantially having a certain shape” may include not only shapes that exactly match the specified shape, but also shapes that approximately match the specified shape. In addition, “substantially coplanar” may include not only features that lie on exactly the same plane, but also features that lie approximately on the same plane.

As used herein, the same insulating material may mean not only the exact same insulating material, but also the same type of insulating material. Thus, compositions of insulating materials may be substantially the same, but specific composition ratios thereof may slightly vary.

As used herein, a cross-sectional shape may refer to a cross-sectional shape of an object when the object is vertically cut, or a cross-sectional shape of the object when the object is viewed in a side-view. In addition, a shape on a plane may be a shape of the object when the object is horizontally cut, or a planar shape of the object when the object is viewed in a top-view or a bottom-view.

As used herein, a lower side, a lower portion, a lower surface, or the like is used to refer to a direction toward the bottom based on a cross-section of a drawing for convenience, while an upper side, an upper portion, an upper surface, or the like is used to refer to the opposite direction. In addition, a side portion, a side surface, or the like is used to refer to a direction, perpendicular to the upper and lower surfaces. However, the directions are defined for convenience of description, and the scope of the claims is not specifically limited by the description of the directions. The concepts of “upper” and “lower” may be interchanged at any time.

As used herein, the term “connected” may not only refer to “directly connected” but also include “indirectly connected” by means of an adhesive layer or the like. The term “electrically connected” may include both of a case in which components are “physically connected” and a case in which components are “not physically connected.” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

As used herein, the term “an example” does not mean the same example embodiment, and is provided to emphasize different unique features. However, the examples presented above do not preclude implementation in combination with features of other examples. For example, a context described in a specific example may be used in other examples, even if it is not described in the other example examples, unless it is described contrary to or inconsistent with the context in the other examples.

The terms used herein describe particular examples only, and the present disclosure is not limited thereby. As used herein, singular forms “a,” “an,” and “the” are intended to include the plural forms as well, unless the context clearly indicates otherwise.

What is claimed is:

1. A printed circuit board comprising:
a plurality of first insulating layers;
a plurality of first wiring layers respectively disposed in the plurality of first insulating layers;
a first glass layer disposed on an upper side of the plurality of first insulating layers, the first glass layer having a thickness less than that of one of the plurality of first insulating layers;
a second glass layer disposed on a lower side of the plurality of first insulating layers, the second glass layer having a thickness less than that of the one of the plurality of first insulating layers;
a second wiring layer disposed on an upper side of the first glass layer; and
a third wiring layer disposed on a lower side of the second glass layer.

2. The printed circuit board of claim 1, further comprising:
a plurality of first wiring vias respectively penetrating one or more of the plurality of first insulating layers, the plurality of first wiring vias connecting the plurality of first wiring layers to each other;
a second wiring via penetrating both an uppermost first insulating layer, among the plurality of first insulating layers, and the first glass layer, the second wiring via connecting an uppermost first wiring layer, among the plurality of first wiring layers, and the second wiring layer to each other; and
a third wiring via penetrating the second glass layer, the third wiring via connecting a lowermost first wiring layer, among the plurality of first wiring layers, and the third wiring layer to each other.

3. The printed circuit board of claim 2, wherein the plurality of first wiring vias are respectively tapered in substantially the same direction as the second wiring via, and are respectively tapered in substantially an opposite direction to the third wiring via.

4. The printed circuit board of claim 2, further comprising:
a second insulating layer disposed between the second glass layer and the third wiring layer,
wherein the third wiring via further penetrates the second insulating layer.

5. The printed circuit board of claim 1, wherein the second and third wiring layers and uppermost and lowermost first wiring layers, among the plurality of first wiring layers, respectively have a thickness less than that of at least one of remaining first wiring layers among the plurality of first wiring layers.

6. The printed circuit board of claim 1, further comprising:
a first solder resist layer disposed on an upper side of the first glass layer, the first solder resist layer having a plurality of first openings respectively exposing at least a portion of the second wiring layer; and
a second solder resist layer disposed on a lower side of the second glass layer, the second solder resist layer having a plurality of second openings respectively exposing at least a portion of the third wiring layer.

7. The printed circuit board of claim 1, further comprising:
a plurality of third insulating layers disposed on an upper side of the first glass layer; and
a plurality of fourth wiring layers respectively disposed on the plurality of third insulating layers,
wherein the plurality of third insulating layers respectively have a thickness less than that of each of the plurality of first insulating layers, the first glass layer, and the second glass layer.

8. The printed circuit board of claim 7, wherein
the plurality of first insulating layers respectively include an organic insulating material, and
the plurality of third insulating layers respectively include an inorganic insulating material.

9. The printed circuit board of claim 7, wherein the plurality of fourth wiring layers respectively have a thickness less than that of each of remaining first wiring layers, excluding uppermost and lowermost first wiring layers, among the plurality of first wiring layers.

10. The printed circuit board of claim 7, further comprising:
a plurality of fourth wiring vias respectively penetrating at least one of the plurality of third insulating layers, the plurality of fourth wiring vias connecting the plurality of fourth wiring layers to each other, the plurality of fourth wiring vias connecting a lowermost fourth wiring layer, among the plurality of fourth wiring layers, and the second wiring layer to each other.

11. The printed circuit board of claim 7, further comprising:
a first solder resist layer disposed on an upper side of the plurality of third insulating layers, the first solder resist layer having a plurality of first openings respectively exposing at least a portion of an uppermost fourth wiring layer, among the plurality of fourth wiring layers; and
a second solder resist layer disposed on a lower side of the second glass layer, the second solder resist layer having a plurality of second openings respectively exposing at least a portion of the third wiring layer.

12. A printed circuit board comprising:
a first substrate portion including a first insulating body, a first glass layer disposed on an upper surface of the first insulating body, a second glass layer disposed on a lower surface of the first insulating body, and a plurality of internal wiring layers respectively disposed in the first insulating body; and
a second substrate portion including a second insulating body disposed on an upper surface of the first glass layer, and a plurality of first external wiring layers respectively disposed on or in the second insulating body,
wherein an insulation distance between two first external wiring layers adjacent to each other in a thickness direction, among the plurality of first external wiring layers, is less than an insulation distance between two internal wiring layers adjacent to each other in the thickness direction, among the plurality of internal wiring layers.

13. The printed circuit board of claim 12, wherein at least one of the plurality of first external wiring layers includes a relatively high-density wiring compared to at least one of the plurality of internal wiring layers.

14. The printed circuit board of claim 12, wherein the first insulating body has a coreless structure including a plurality of build-up layers.

15. The printed circuit board of claim 12, wherein
the first insulating body includes one or more of a non-photosensitive organic insulating material and a photosensitive organic insulating material, and
the second insulating body includes one or more of a silicon oxide film and a silicon nitride film.

16. The printed circuit board of claim 12, further comprising:
a second external wiring layer disposed on a lower surface of the second glass layer.

17. A printed circuit board comprising:
a plurality of first insulating layers;
a plurality of first wiring layers respectively disposed in the plurality of first insulating layers;
a plurality of first wiring vias respectively penetrating one or more of the plurality of first insulating layers, the plurality of first wiring vias connecting the plurality of first wiring layers to each other;
a first glass layer disposed on an upper side of the plurality of first insulating layers;
a second wiring layer disposed on an upper side of the first glass layer;
a second wiring via penetrating at least through the first glass layer, the second wiring via connecting an uppermost first wiring layer, among the plurality of first wiring layers, and the second wiring layer to each other; and
a second glass layer disposed on a lower side of the plurality of first insulating layers;
a third wiring layer disposed on a lower side of the second glass layer; and
a third wiring via penetrating the second glass layer, the third wiring via connecting a lowermost first wiring layer, among the plurality of first wiring layers, and the third wiring layer to each other,
wherein the plurality of first wiring vias are respectively tapered in substantially the same direction as the second wiring via, and are respectively tapered in substantially an opposite direction to the third wiring via, and
the third wiring via is tapered from the third wiring layer to the lowermost first wiring layer.

18. The printed circuit board of claim 17, wherein the second wiring via also penetrates through an uppermost first insulating layer, among the plurality of first insulating layers.

19. The printed circuit board of claim 17, further comprising:
a second insulating layer disposed between the second glass layer and the third wiring layer,
wherein the third wiring via further penetrates the second insulating layer.

20. The printed circuit board of claim 17, further comprising:
a plurality of third insulating layers disposed on an upper side of the first glass layer; and
a plurality of fourth wiring layers respectively disposed on the plurality of third insulating layers,
wherein the plurality of third insulating layers respectively have a thickness less than that of each of the plurality of first insulating layers, the first glass layer, and the second glass layer.
